(19) United States
(12) Patent Application Publication
(10) Pub. No.: US 2011/0005566 A1
(43) Pub. Date: Jan. 13, 2011

(54) PHOTOVOLTAIC CELL MODULE AND METHOD OF MAKING THE SAME

(75) Inventors: Chih-Jeng HUANG, KAOHSIUNG CITY (TW); Yu-Hua WU, TAICHUNG COUNTY (TW); Liang-Tang WANG, TAINAN CITY (TW); Wei-Teng CHANG, TAINAN COUNTY (TW)

Correspondence Address: BRIAN M. MCINNIS, 12th Floor, Ruttonjee House, 11 Duddell Street, Hong Kong, HK

(73) Assignee: CHI-MEI ENERGY CORP., TAINAN COUNTY (TW)

(21) Appl. No.: 12/498,370

(22) Filed: Jul. 7, 2009

(51) Int. Cl. H01L 31/042; H01L 31/18

(52) U.S. Cl. 136/244; 438/68; 257/E21.238

(57) ABSTRACT

A photovoltaic cell module and a method of making the same are provided. The photovoltaic cell module includes a first cell including a first transparent conductive substrate, a first photovoltaic conversion layer, and a first electrode layer, at least a second cell electrically connected to the first cell in series; and a second electrode layer electrically connected to the second cell. In the first cell, the first photovoltaic conversion layer is disposed on the first transparent conductive substrate. The first electrode layer is disposed on the first photovoltaic conversion layer and electrically connected to the first transparent conductive substrate. In addition, the present invention also provides the method of making the photovoltaic cell module.

### FIELD OF THE INVENTION

This invention relates to a photovoltaic cell module and a method of making the same, and more particularly, to a photovoltaic cell module configured to convert solar power to electric power and a method of making the same.

### BACKGROUND OF THE INVENTION

Due to energy shortages, many countries have developed substitute energy resources over many years, wherein a photovoltaic battery, such as a solar battery, is the major substitute energy resource developed by the countries. The solar battery can inexhaustibly produce energy, and is convenient to use. The solar battery does not produce pollution, waste products, and noise, and has a long service life. Because the solar battery has the aforementioned advantages, the fabrication technology of the solar battery is very important.

The solar battery is different from an alkaline battery. The solar battery can convert solar power to electric power without needing electrolytes to transmit conductive ions. The solar battery has P-type and N-type semiconductors. When light irradiates the solar battery, lots of free electrons are produced and move to the N-type semiconductors, thereby generating currents and a potential difference, wherein the potential difference is induced by the currents, so that the solar battery can store electric power in the form of a potential difference at the interface between the N-type semiconductors and P-type semiconductors.

Please refer to FIG. 1 and FIG. 2. FIG. 1 is a curve diagram showing the relationship between the current/power values and the voltage values of a conventional battery module under a normal status. FIG. 2 is a curve diagram showing the relationship between the current/power values and the voltage values of a conventional battery module in under damaged status. In the conventional solar battery module, the output current values may decrease abnormally, and is referred to as the S-curve effect. As shown in FIG. 2, a region enclosed by dot lines 20 shows the so-called S-curve effect, and the current values in the region abnormally decrease. When the S-curve effect occurs, the output current of the solar battery module is decreased, and accordingly the output power thereof is decreased.

### SUMMARY OF THE INVENTION

An aspect of the present invention is to provide a photovoltaic cell module and a method for making the photovoltaic cell module to overcome the shortcomings caused by the S-curve effect.

According to an embodiment of the present invention, the photovoltaic cell module includes a first cell, at least one second cell and a second electrode layer. The first cell includes a first transparent conductive substrate, a first photovoltaic conversion layer and a first electrode layer, wherein the first photovoltaic conversion layer is disposed on the first transparent conductive substrate, and the first electrode layer is disposed on the first photovoltaic conversion layer and electrically connected to the first transparent conductive substrate. The second cells are electrically connected to the first cell in series. The second electrode layer is electrically connected to the at least one second cell.

According to another embodiment of the present invention, the photovoltaic cell module includes a transparent conductive substrate, a photovoltaic conversion layer, and an electrode layer. The transparent conductive substrate includes a first substrate portion, a second substrate portion, and third substrate portion, wherein a first substrate portion isolation space is located between the first substrate portion and the second substrate portion, and a second substrate portion isolation space is located between the second substrate portion and the third substrate portion. The photovoltaic conversion layer is disposed on the transparent conductive substrate and includes a first photovoltaic conversion portion disposed on the first substrate portion, a second photovoltaic conversion portion disposed on the second substrate portion, and a third photovoltaic conversion portion disposed on the third substrate portion, wherein a first conversion portion isolation space is located between the first photovoltaic conversion portion and the second photovoltaic conversion portion, and a second conversion portion isolation space is located between the second photovoltaic conversion portion and the third photovoltaic conversion portion. The electrode layer is disposed on the photovoltaic conversion layer and includes a first electrode portion, a second electrode portion, and a third electrode. The first electrode portion is disposed on the first photovoltaic conversion portion and in the first conversion portion isolation space to be electrically connected to the second substrate portion. The second electrode portion is disposed on the second photovoltaic conversion portion and in the second conversion portion isolation space to be electrically connected to the second substrate portion. The third electrode is disposed on the third photovoltaic conversion portion and electrically connected to the third substrate portion. A first electrode portion isolation space is located between the first electrode portion and the second electrode portion, and a second electrode portion isolation space is located between the second electrode portion and the third electrode portion.

According to another embodiment of the present invention, in the method of making the photovoltaic cell module, a transparent conductive substrate is initially provided. Then, a first cutting step is performed to the transparent conductive substrate into a first substrate portion, a second substrate portion, and a third substrate portion, wherein a first substrate isolation space is located between the first substrate portion and the second substrate portion, and a second substrate isolation space is located between the second substrate portion and the third substrate portion. Thereafter, a photovoltaic conversion layer is formed on the transparent conductive substrate and in the substrate isolation spaces. Then, a second cutting step is performed to cut the photovoltaic conversion layer into a first photovoltaic conversion portion, a second photovoltaic conversion portion and a third photovoltaic conversion portion, and form a through opening in the third photovoltaic conversion portion, wherein a first conversion portion isolation space is located between the first photovoltaic conversion portion and the second photovoltaic conversion portion, and a second conversion portion isolation space is located between the second photovoltaic conversion portion and the third photovoltaic conversion portion. Thereafter, an electrode layer is formed on the photovoltaic conversion layer and in the conversion portion isolation spaces and the through opening, and thereby the electrode layer is electrically connected to the second substrate portion and the third substrate portion. Then, a third cutting step is performed to cut the electrode layer into a first electrode portion, a second electrode portion, and a third electrode portion, wherein a first electrode portion isolation space is located between the first electrode portion and the second electrode portion, and a second electrode portion isolation space is located between the second electrode portion and the third electrode portion.

According to still another embodiment of the present invention, in the method of making the photovoltaic cell module, a transparent conductive substrate is initially provided. Then, a first cutting step is performed to cut the transparent conductive substrate into a first substrate portion, a second substrate portion, and a third substrate portion, wherein a first substrate isolation space is located between the first substrate portion and the second substrate portion, and a second substrate isolation space is located between the second substrate portion and the third substrate portion. Thereafter, a conductive bump is formed on the third substrate portion. Then, a photovoltaic conversion layer is formed on the transparent conductive substrate and in the substrate isolation spaces. Then, a second cutting step is performed to cut the photovoltaic conversion layer into a first photovoltaic conversion portion, a second photovoltaic conversion portion and a third photovoltaic conversion portion, wherein a first conversion portion isolation space is located between the first photovoltaic conversion portion and the second photovoltaic conversion portion, and a second conversion portion isolation space is located between the second photovoltaic conversion portion and the third photovoltaic conversion portion. Thereafter, an electrode layer is formed on the photovoltaic conversion layer and the conductive bump, and in the conversion isolation spaces, and thereby the electrode layer is electrically connected to the second substrate portion and the third substrate portion via the conversion isolation spaces and the conductive bump. Then, a third cutting step is performed to cut the electrode layer into a first electrode portion, a second electrode portion, and a third electrode portion, wherein a first electrode portion isolation space is located between the first electrode portion and the second electrode portion, and a second electrode portion isolation space is located between the second electrode portion and the third electrode portion.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a curve diagram showing the relationship between the current/power values and the voltage values of a conventional battery module in a normal status;

FIG. 2 is a is a curve diagram showing the relationship between the current/power values and the voltage values of a conventional battery module in a damaged status;

FIG. 3 is a diagram showing the structure of a photovoltaic cell module according to an embodiment of the present invention;

FIG. 4 is a diagram showing the structure of a photovoltaic module according to another embodiment of the present invention;

FIG. 5 is a diagram showing the structure of a photovoltaic module according to still another embodiment of the present invention;

FIG. 6 is a diagram showing the structure of a photovoltaic module according to further another embodiment of the present invention;

FIG. 7 is flow chart showing the making method of a photovoltaic module according to further another embodiment of the present invention;

FIG. 8a to FIG. 8f are sectional diagrams respectively showing photovoltaic module corresponding to the steps of the making method;

FIG. 9 is flow chart showing the making method of a photovoltaic module according to further another embodiment of the present invention; and

FIG. 10a to FIG. 10g are sectional diagrams respectively showing photovoltaic module corresponding to the steps of the making method.

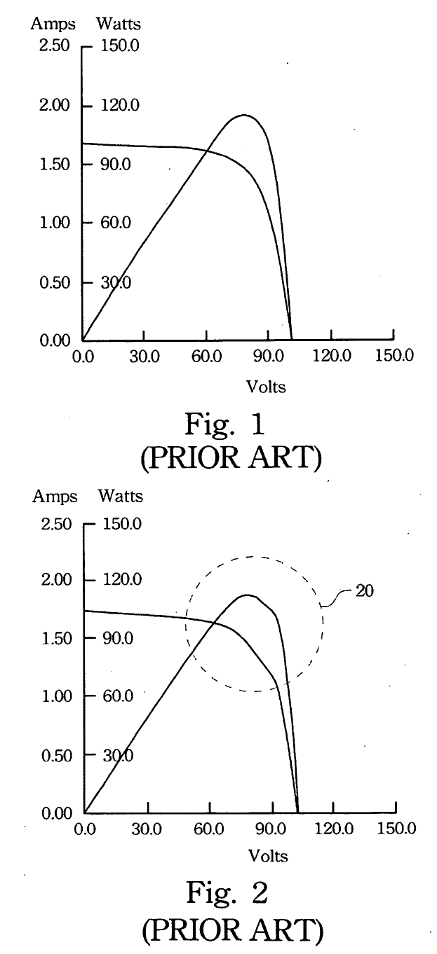

### DETAILED DESCRIPTION OF THE PREFERRED EMBODIMENT

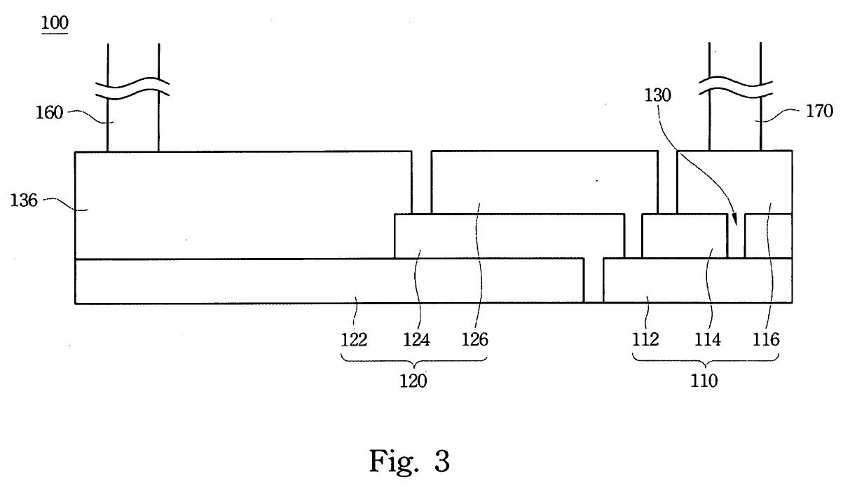

In order to make the illustration of the present invention more explicit and complete, the following description is stated with reference to FIG. 3 through FIG. 10g.

Referring to FIG. 3. FIG. 3 is a diagram showing the structure of a photovoltaic cell module 100 according to an embodiment of the present invention. The photovoltaic cell module 100 includes a first cell 110, at least one second cell 120 and an electrode layer 136. The first cell 110 includes a transparent conductive substrate 112, a photovoltaic conversion layer 114, and an electrode layer 116. The photovoltaic conversion layer 114 is disposed on the transparent conductive substrate 112. When light irradiates the photovoltaic conversion layer 114, the photovoltaic conversion layer 114 can convert the power of the lights to electric power. The electrode layer 116 is disposed on the conversion layer 114. The conversion layer 114 has a through opening 130 which can be a through hole penetrating the conversion layer 114, or an opening dividing the conversion layer 114 into two separated parts, and thus the electrode layer 116 can be connected to the transparent conductive substrate 112 via the through opening 130.

The second cell 120 includes a transparent conductive substrate 122, a photovoltaic conversion layer 124, and an electrode layer 126. The transparent conductive substrate 122 is electrically connected to the electrode layer 136 to be connected to an external device via the electrode layer 136. The photovoltaic conversion layer 124 is disposed on the photovoltaic conversion layer 124. The photovoltaic conversion layer 124 receives light and converts the power of the light into electric power. The electrode layer 126 is disposed on the photovoltaic conversion layer 124, and electrically connected to the transparent conductive substrate 112 to connect the first cell 110 and the second cell 120 in series.

In general, two conductive lines 160 and 170 are respectively formed on the electrode layer 160 and 170 when the photovoltaic module 100 is formed, and thereby the photovoltaic module 100 can be electrically connected to the external device via the conductive lines 160 and 170 and provide the electric power to the external device.

In this embodiment, because the photovoltaic conversion layer 114 of the first cell 110 has the through opening 130, the electrode layer 116 of the first cell 110 can be electrically connected to the transparent conductive substrate 112 to disable the power generation function of the first cell 110. Based on the results of some experiments, the terminal cell 110 of the photovoltaic module 100 would be damaged in the process of making the photovoltaic module, for example: a blasting process. Therefore, sacrificing the terminal cell 110 can improve the output current stability of the photovoltaic module 100, and thereby other normal cells (such as cell 120) are protected by the sacrificed terminal cell 110.

It is noted that the photovoltaic module 100 may include a plurality of second cell 120 connected in series to provide higher output voltage and output current to the external device. Further, in this embodiment, the transparent conductive substrates are made from transparent conductive oxide (TCO). The photovoltaic conversion layers are made from silicon semiconductor. The material of the electrode layers is selected from titanium, silver, Ga doped Zinc Oxide (GZO), and the combination thereof.

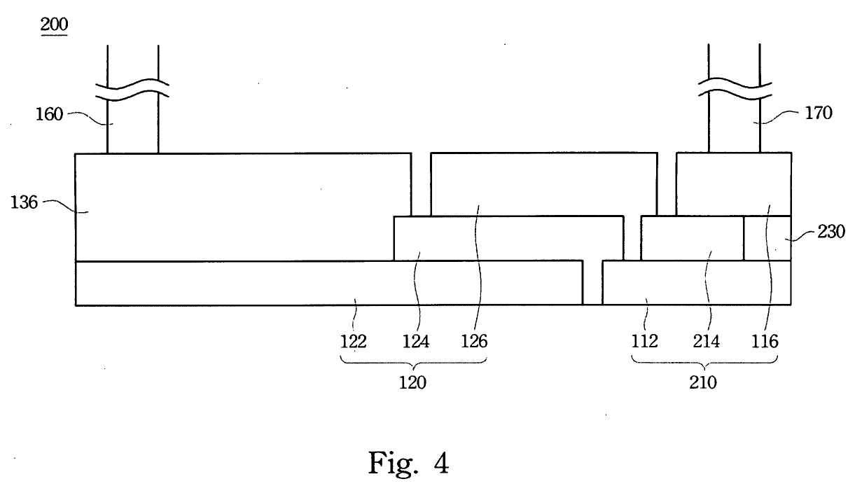

Refer to FIG. 4. FIG. 4 is a diagram showing the structure of a photovoltaic module 200 according to another embodiment of the present invention. The structure of the photovoltaic module 200 is similar to that of the photovoltaic module 100, but the difference therebetween is in that the cell 210 of the photovoltaic module 200 includes a conductive bump 230 disposed between the transparent conductive 112 and the electrode layer 116, but the photovoltaic module 100 has the through opening 130 formed in the photovoltaic conversion layer 214. In this embodiment, the electrical connection between the transparent conductive substrate 112 and the electrode layer 116 is implemented via the conductive bump 230 instead of the through opening 130, and thus the through opening 130 does not need to be formed in the photovoltaic conversion layer 214.

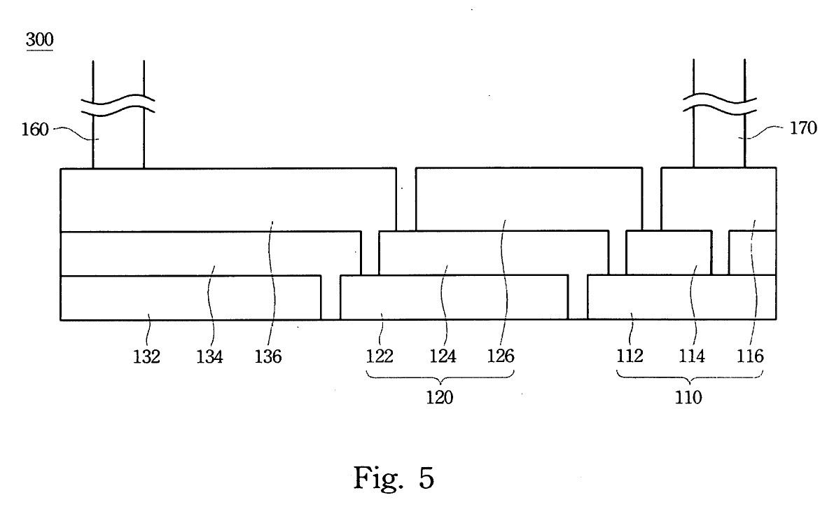

Referring to FIG. 5. FIG. 5 is a diagram showing the structure of a photovoltaic module 300 according to still another embodiment of the present invention. The photovoltaic module 300 is similar to the photovoltaic module 100, but the difference is in that the photovoltaic module 300 further includes a transparent conductive substrate 132 and a photovoltaic conversion layer 134. The photovoltaic conversion layer 134 is disposed on the transparent conductive substrate 132, and the electrode layer 136 is disposed on the photovoltaic conversion layer 134.

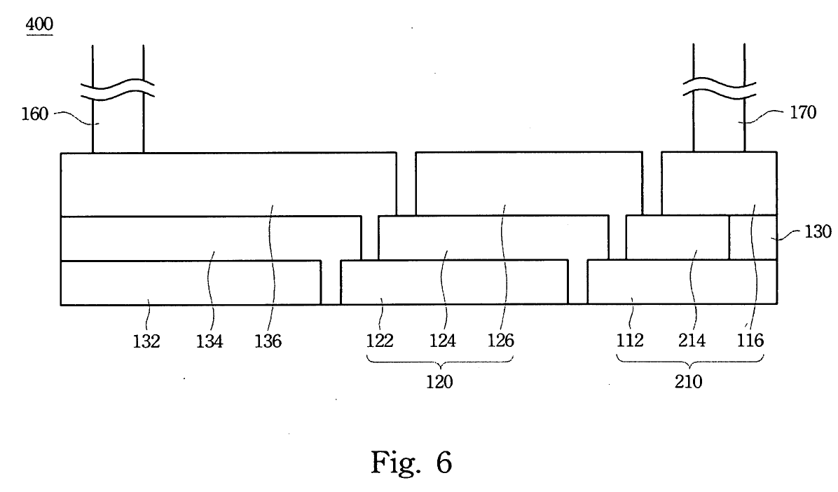

Referring to FIG. 6. FIG. 6 is a diagram showing the structure of a photovoltaic module 400 according to further another embodiment of the present invention. The photovoltaic module 400 is similar to the photovoltaic module 200, but the difference is in that the photovoltaic module 400 further includes the transparent conductive substrate 132 and the photovoltaic conversion layer 134. The photovoltaic conversion layer 134 is disposed on the transparent conductive substrate 132, and the electrode layer 136 is disposed on the photovoltaic conversion layer 134.

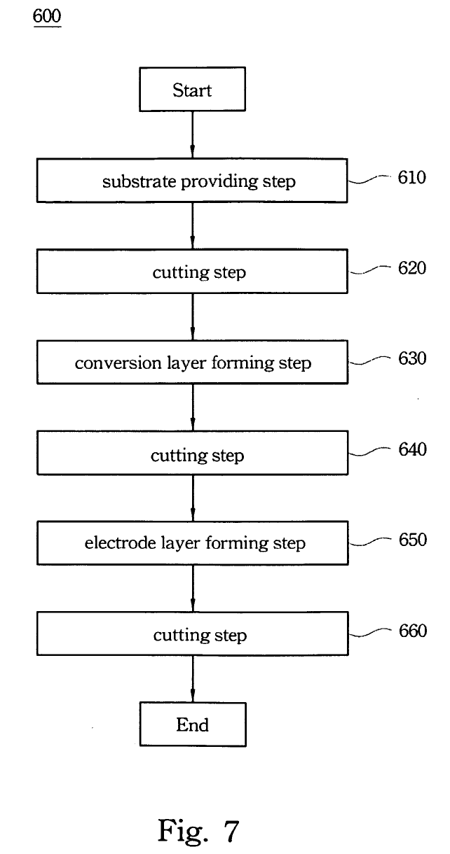

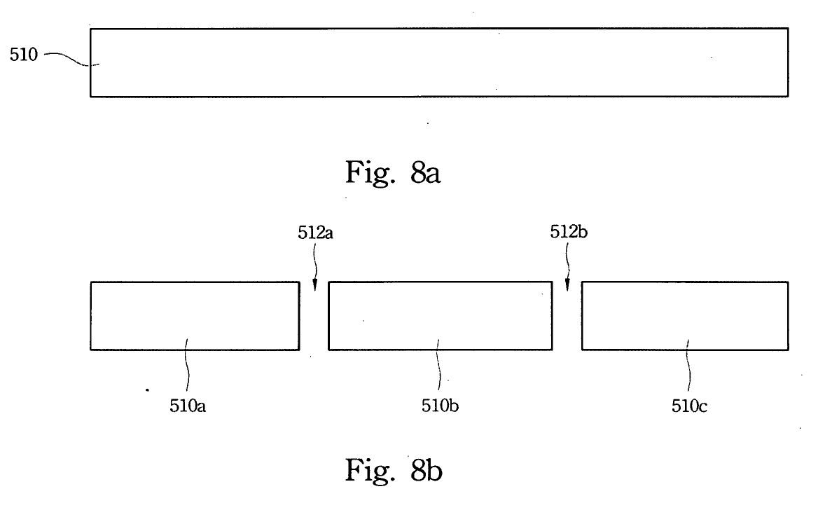

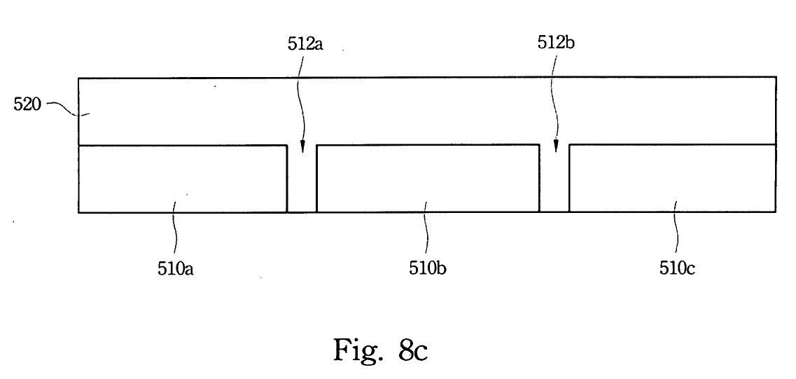

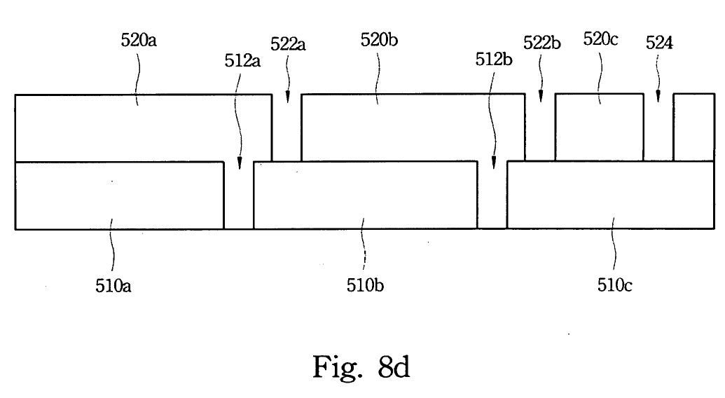

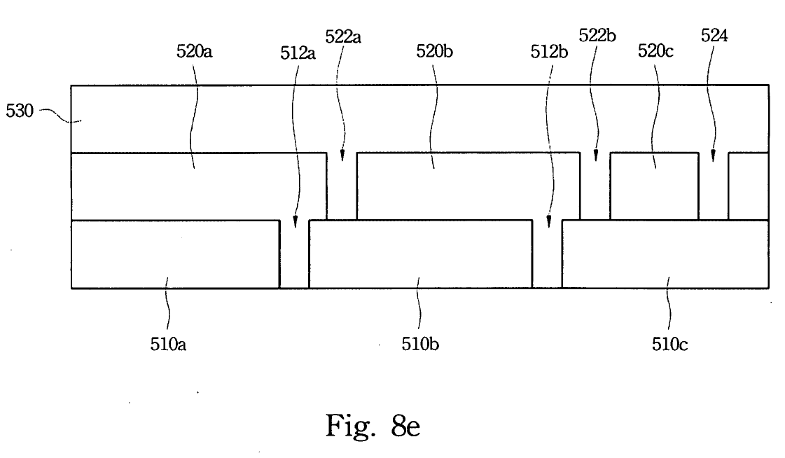

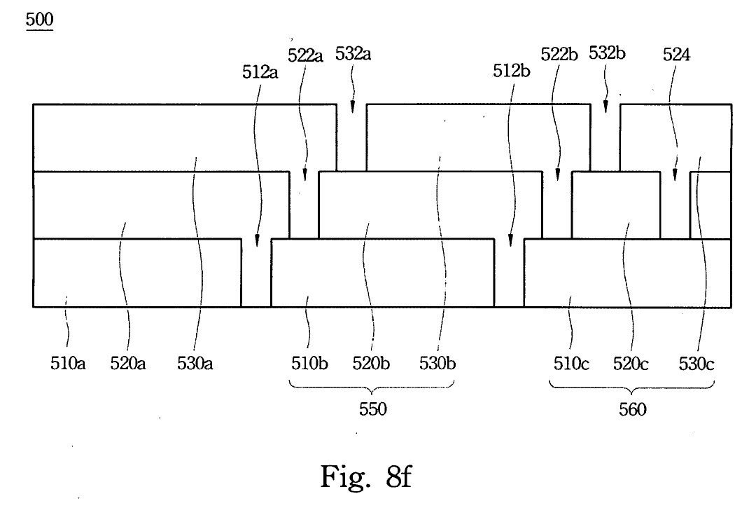

Refer to FIG. 7 and FIG. 8a to FIG. 8f. FIG. 7 is flow chart showing the making method 600 of a photovoltaic module 500 according to further another embodiment of the present invention. FIG. 8a to FIG. 8f are sectional diagrams respectively showing photovoltaic module 500 corresponding to the steps of the making method 600. In the making method 600, a substrate-providing step 610 is initially performed to provide a transparent conductive substrate 510, as shown in FIG. 8a. Thereafter, a cutting step 620 is performed to cut the transparent conductive substrate 510 into substrate portions 510a, 510b, and 510c, and respectively form substrate portion isolation spaces 512a and 512b between the substrate portions 510a and 510b, and the substrate portions 510b and 510c, as shown in FIG. 8b.

Then, a conversion-layer-forming step 630 is performed to form a photovoltaic conversion layer 520 on the transparent conductive substrate 510, as shown in FIG. 8c. In this embodiment, in addition to be formed on the transparent conductive substrate 510, the photovoltaic conversion layer 520 is also formed in the substrate portion isolation spaces 512a and 512b. In the other embodiment of the present invention, the substrate portion isolation spaces 512a and 512b can be filled with insulation material, thus the photovoltaic conversion layer 520 can be then formed on the transparent conductive substrate 510 and the insulation material. Thereafter, a cutting step 640 is performed to cut the photovoltaic conversion layer 520 into photovoltaic conversion portions 520a, 520b, and 520c, and form a through opening 524 in the photovoltaic conversion portion 520c, as shown in FIG. 8d, wherein a conversion portion isolation space 522a is formed between the photovoltaic conversion portions 520a and 520b, and a conversion portion isolation space 522b is formed between the photovoltaic conversion portions 520b and 520c.

Then, an electrode-layer-forming step 650 is performed to form an electrode layer 530 on the photovoltaic conversion layer 520, as shown in FIG. 8e. In this embodiment, in addition to be formed on the photovoltaic conversion layer 520, the electrode layer 530 is also formed in the conversion portion isolation spaces 522a and 522b. In other embodiments of the present invention, the conversion portion isolation spaces 522a and 522b can be filled with conductive material, and thus the electrode layer 530 can be then formed on the photovoltaic conversion layer 520 and the conductive material. Thereafter, a cutting step 660 is performed to cut the electrode layer 530 into electrode portions 530a, 530b, and 530c, and respectively form electrode portion isolation spaces 532a and 532b between the electrode portions 530a and 530b, and the electrode portions 530b and 530c, as shown in FIG. 8f.

The photovoltaic module 500 is similar to the photovoltaic module 300, wherein the substrate portion 510b, the conversion portion 520b, and the electrode portion 530b of the photovoltaic module 500 constitute a cell 550 which is corresponding to the second cell 120 of the photovoltaic module 300; the substrate portion 510c, the conversion portion 520c, and the electrode portion 530c of the photovoltaic module 500 constitute a cell 560 which is corresponding to the first cell 110 of the photovoltaic module 300.

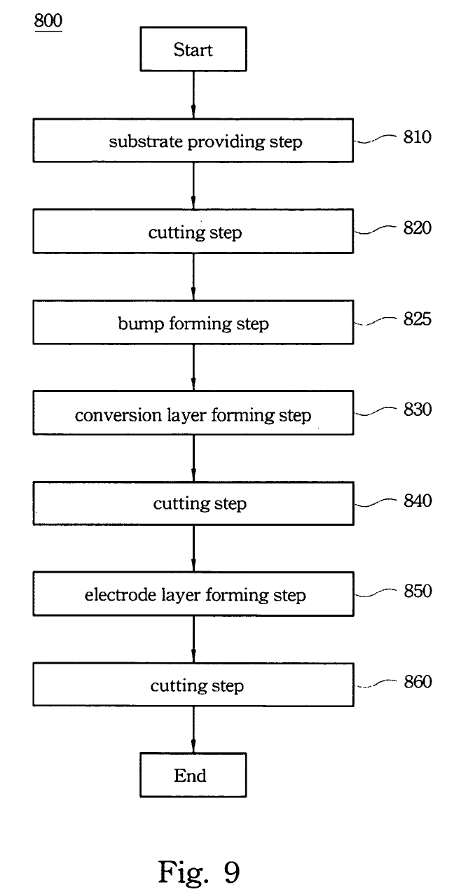

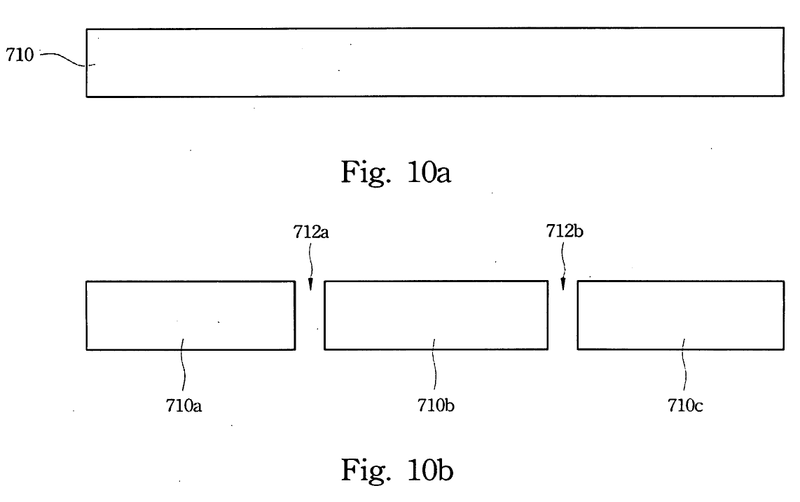

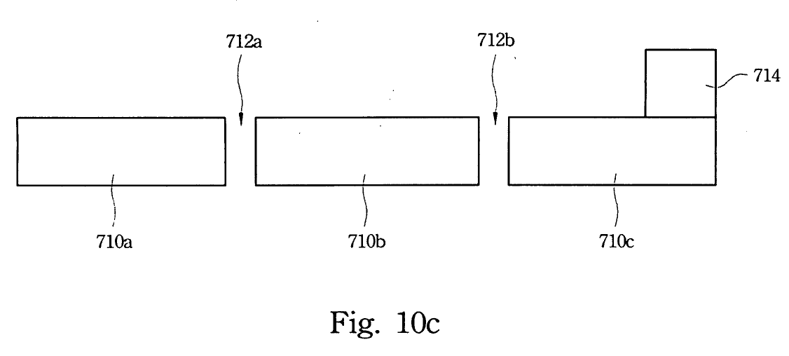

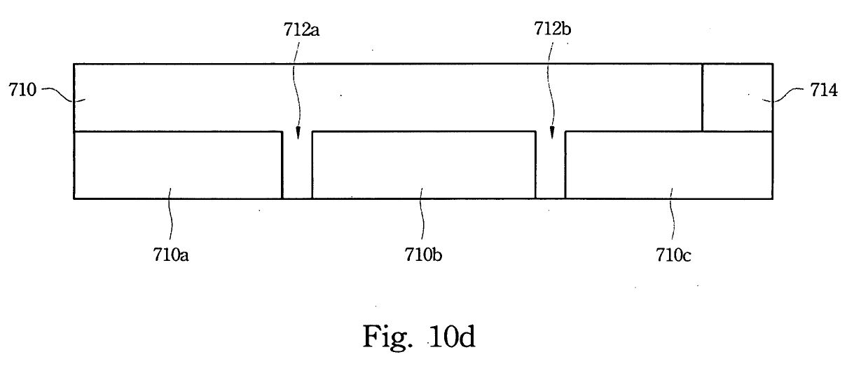

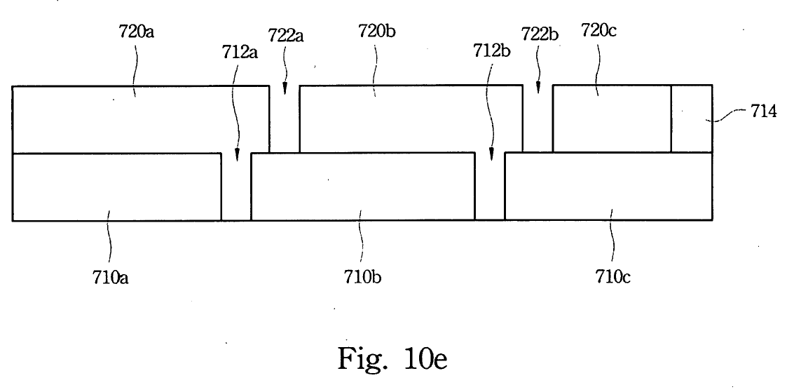

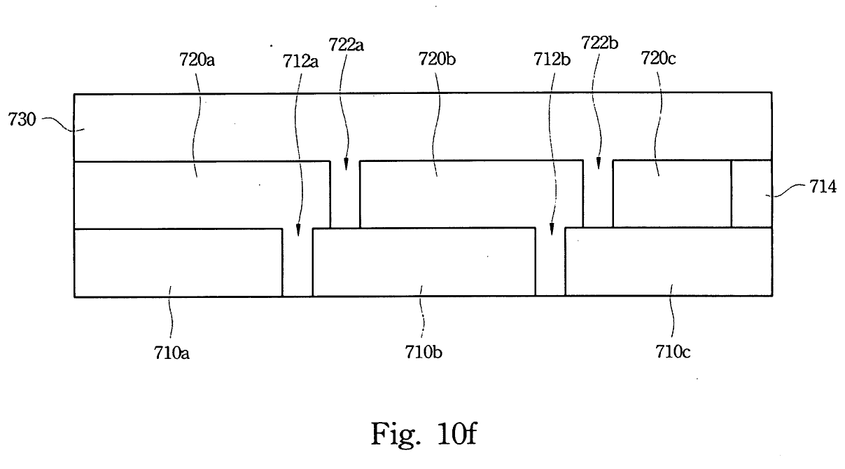

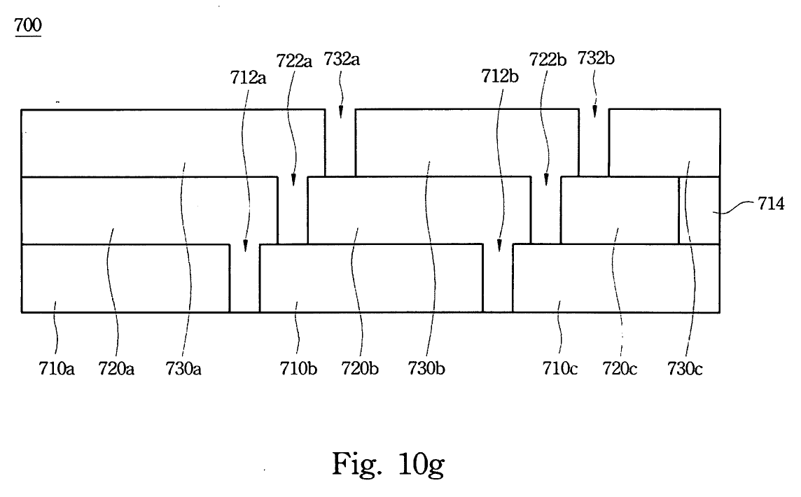

Refer to FIG. 9 and FIG. 10a to FIG. 10g. FIG. 9 is flow chart showing the making method 800 of a photovoltaic module 700 according to further another embodiment of the present invention. FIG. 10a to FIG. 10g are sectional diagrams respectively showing photovoltaic module 500 corresponding to the steps of the making method 600. In the making method 800, a substrate-providing step 810 is initially performed to provide a transparent conductive substrate 710, as shown in FIG. 10a. Thereafter, a cutting step 820 is performed to cut the transparent conductive substrate 710 into substrate portions 710a, 710b, and 710c, and respectively form substrate portion isolation spaces 712a and 712b between the substrate portions 710a and 710b, and the substrate portions 710b and 710c, as shown in FIG. 10b.

Then, a bump-forming step 825 is performed to form a conductive bump 714 on the substrate portion 720c, as shown in FIG. 10c.

Thereafter, a conversion-layer-forming step 830 is performed to form a photovoltaic conversion layer 720 on the transparent conductive substrate 710, as shown in FIG. 10d. In this embodiment, in addition to be formed on the transparent conductive substrate 710, the photovoltaic conversion layer 720 is also formed in the substrate portion isolation spaces 712a and 712b. In other embodiment of the present invention, the substrate portion isolation spaces 712a and 712b can be filled with insulation material, thus the photovoltaic conversion layer 720 can be then formed on the transparent conductive substrate 710 and the insulation material. Thereafter, a cutting step 840 is performed to cut the photovoltaic conversion layer 720 into photovoltaic conversion portions 720a, 720b, and 720c, as shown in FIG. 10e, wherein a conversion portion isolation space 722a is formed between the photovoltaic conversion portions 720a and 720b, and a conversion portion isolation space 722b is formed between the photovoltaic conversion portions 770b and 720c.

Then, an electrode-layer-forming step 850 is performed to form an electrode layer 730 on the photovoltaic conversion layer 720, as shown in FIG. 10f. In this embodiment, in addition to be formed on the photovoltaic conversion layer 720, the electrode layer 730 is also formed in the conversion portion isolation spaces 722a and 722b. In other embodiments of the present invention, the conversion portion isolation spaces 722a and 722b can be filled with conductive material, thus the electrode layer 730 can be then formed on the photovoltaic conversion layer 720 and the conductive material. Thereafter, a cutting step 860 is performed to cut the electrode layer 730 into electrode portions 730a, 730b, and 730c, and respectively form electrode portion isolation spaces 732a and 732b between the electrode portions 730a and 730b, and the electrode portions 730b and 730c, as shown in FIG. 10g.

The photovoltaic module 700 is similar to the photovoltaic module 400, wherein the substrate portion 710a, the conversion portion 720a, and the electrode portion 730a of the photovoltaic module 700 constitute a cell which is corresponding to the second cell 120 of the photovoltaic module 400; the substrate portion 710c, the conversion portion 720c, and the electrode portion 730c of the photovoltaic module 700 constitute another cell which is corresponding to the first cell 210 of the photovoltaic module 400.

As is understood by a person skilled in the art, the foregoing embodiments of the present invention are strengths of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A photovoltaic cell module, comprising:
a first cell comprising;
a first transparent conductive substrate;
a first photovoltaic conversion layer disposed on the first transparent conductive substrate; and
a first electrode layer disposed on the first photovoltaic conversion layer, wherein the first electrode is electrically connected to the first transparent conductive substrate;
at least one second cell electrically connected to the first cell in series; and
a second electrode layer electrically connected to the at least one second cell.

2. The photovoltaic cell module of claim 1, wherein the first photovoltaic conversion layer has a through opening, and the first electrode layer is connected to the first transparent conductive substrate through the through opening.

3. The photovoltaic cell module of claim 1, further comprising a conductive bump disposed between the first transparent conductive substrate and the first electrode layer.

4. The photovoltaic cell module of claim 1, wherein each of the second cells comprises:
a second transparent conductive substrate electrically connected the second electrode layer;
a second photovoltaic conversion layer disposed on the second transparent conductive substrate; and
a third electrode layer disposed on the second photovoltaic conversion layer, wherein the third electrode is electrically connected to the first transparent conductive substrate.

5. The photovoltaic cell module of claim 4, further comprising:
a third transparent conductive substrate; and
a third photovoltaic conversion layer disposed on the third transparent conductive substrate, wherein the second electrode layer is disposed on the third transparent conductive substrate.

6. The photovoltaic cell module of claim 1, wherein the transparent conductive substrates are made from transparent conductive oxide (TCO).

7. The photovoltaic cell module of claim 1, wherein the photovoltaic conversion layers are made from silicon semiconductor.

8. The photovoltaic cell module of claim 1, wherein the material of the electrode layers is selected from titanium, silver, Ga doped Zinc Oxide (GZO), and the combination thereof.

9. A photovoltaic cell module, comprising:
a transparent conductive substrate comprising a first substrate portion, a second substrate portion, and third substrate portion, wherein a first substrate portion isolation space is located between the first substrate portion and the second substrate portion, and a second substrate portion isolation space is located between the second substrate portion and the third substrate portion;
a photovoltaic conversion layer disposed on the transparent conductive substrate, wherein the photovoltaic conversion layer comprises:
a first photovoltaic conversion portion disposed on the first substrate portion;
a second photovoltaic conversion portion disposed on the second substrate portion; and
a third photovoltaic conversion portion disposed on the third substrate portion;
wherein a first conversion portion isolation space is located between the first photovoltaic conversion portion and the second photovoltaic conversion portion, and a second conversion portion isolation space is located between the second photovoltaic conversion portion and the third photovoltaic conversion portion; and
an electrode layer disposed on the photovoltaic conversion layer, wherein the electrode layer comprises:
a first electrode portion disposed on the first photovoltaic conversion portion, and disposed in the first conversion portion isolation space to be electrically connected to the second substrate portion;
a second electrode portion disposed on the second photovoltaic conversion portion, and disposed in the second conversion portion isolation space to be electrically connected to the second substrate portion; and
a third electrode disposed on the third photovoltaic conversion portion, wherein the third electrode is electrically connected to the third substrate portion;
wherein a first electrode portion isolation space is located between the first electrode portion and the second electrode portion, and a second electrode portion isolation space is located between the second electrode portion and the third electrode portion.

10. The photovoltaic cell module of claim 9, wherein the third photovoltaic conversion layer has a through opening, and the third electrode portion is electrically connected to the third substrate portion via the through opening.

11. The photovoltaic cell module of claim 9, wherein the transparent conductive substrate is made from transparent conductive oxide (TCO).

12. The photovoltaic cell module of claim 9, wherein the photovoltaic conversion layer is made from silicon semiconductor.

13. The photovoltaic cell module of claim 9, wherein the material of the electrode layer is selected from titanium, silver, Ga doped Zinc Oxide (GZO), and the combination thereof.

14. A method of making a photovoltaic cell module, comprising:
providing a transparent conductive substrate;
performing a first cutting step to cut the transparent conductive substrate into a first substrate portion, a second substrate portion, and a third substrate portion, wherein a first substrate isolation space is located between the first substrate portion and the second substrate portion, and a second substrate isolation space is located between the second substrate portion and the third substrate portion;
forming a photovoltaic conversion layer on the transparent conductive substrate and in the substrate isolation spaces;
performing a second cutting step to cut the photovoltaic conversion layer into a first photovoltaic conversion portion, a second photovoltaic conversion portion and a third photovoltaic conversion portion, and form a through opening in the third photovoltaic conversion portion, wherein a first conversion portion isolation space is located between the first photovoltaic conversion portion and the second photovoltaic conversion portion, and a second conversion portion isolation space is located between the second photovoltaic conversion portion and the third photovoltaic conversion portion;
forming an electrode layer on the photovoltaic conversion layer and in the conversion portion isolation spaces and the through opening, and thereby the electrode layer is electrically connected to the second substrate portion and the third substrate portion; and
performing a third cutting step to cut the electrode layer into a first electrode portion, a second electrode portion, and a third electrode portion, wherein a first electrode portion isolation space is located between the first electrode portion and the second electrode portion, and a second electrode portion isolation space is located between the second electrode portion and the third electrode portion.

15. The method of claim 14, wherein the transparent conductive substrate is made from transparent conductive oxide (TCO).

16. The method of claim 14, wherein the photovoltaic conversion layer is made from silicon semiconductor.

17. The method of claim 14, wherein the material of the electrode layer is selected from titanium, silver, Ga doped Zinc Oxide (GZO), and the combination thereof.

18. A method of making a photovoltaic cell module, comprising:
providing a transparent conductive substrate;
performing a first cutting step to cut the transparent conductive substrate into a first substrate portion, a second substrate portion, and a third substrate portion, wherein a first substrate isolation space is located between the first substrate portion and the second substrate portion, and a second substrate isolation space is located between the second substrate portion and the third substrate portion;
forming a conductive bump on the third substrate portion;
forming a photovoltaic conversion layer on the transparent conductive substrate and in the substrate isolation spaces;
performing a second cutting step to cut the photovoltaic conversion layer into a first photovoltaic conversion portion, a second photovoltaic conversion portion and a third photovoltaic conversion portion, wherein a first conversion portion isolation space is located between the first photovoltaic conversion portion and the second photovoltaic conversion portion, and a second conversion portion isolation space is located between the second photovoltaic conversion portion and the third photovoltaic conversion portion;
forming an electrode layer on the photovoltaic conversion layer and the conductive bump, and in the conversion isolation spaces, and thereby the electrode layer is electrically connected to the second substrate portion and the third substrate portion via the conversion isolation spaces and the conductive bump; and
performing a third cutting step to cut the electrode layer into a first electrode portion, a second electrode portion, and a third electrode portion, wherein a first electrode portion isolation space is located between the first electrode portion and the second electrode portion, and a second electrode portion isolation space is located between the second electrode portion and the third electrode portion.

19. The method of claim 18, wherein the transparent conductive substrate is made from transparent conductive oxide (TCO).

20. The method of claim 18, wherein the photovoltaic conversion layer is made from silicon semiconductor.

21. The method of claim 18, wherein the material of the electrode layer is selected from titanium, silver, Ga doped Zinc Oxide (GZO), and the combination thereof.
